(19) United States
(12) Patent Application Publication
(10) Pub. No.: US 2014/0285256 A1
(43) Pub. Date: Sep. 25, 2014

(54) TRANSCONDUCTANCE ADJUSTING CIRCUIT, FILTER CIRCUIT, AND ELECTRONIC APPARATUS

(71) Applicant: Sony Corporation, Tokyo (JP)

(72) Inventors: Syou Mitsuishi, Fukuoka (JP); Toshio Suzuki, Fukuoka (JP); Nobuhiko Shigyo, Fukuoka (JP); Kazutoshi Ono, Fukuoka (JP); Jyunichirou Hatanaka, Fukuoka (JP)

(73) Assignee: Sony Corporation, Tokyo (JP)

(21) Appl. No.: 14/208,174

(22) Filed: Mar. 13, 2014

(30) Foreign Application Priority Data
Mar. 22, 2013 (JP) 2013-060154

(51) Int. Cl. H03H 11/04; H03F 3/45

(52) U.S. Cl. CPC H03H 11/0472; H03F 3/45071
USPC 327/552; 330/260

(57) ABSTRACT

A transconductance adjusting circuit includes: a voltage generating section configured to generate a first differential voltage; a first transconductance amplifier configured to receive the first differential voltage through a first positive-phase voltage transmission line and a first reversed-phase voltage transmission line, and output a second differential voltage through a second positive-phase voltage transmission line and a second reversed-phase voltage transmission line; a first control section configured to receive the second differential voltage and supply a first control voltage to the first transconductance amplifier; a second control section configured to receive the second differential voltage and supply a second control voltage to the first transconductance amplifier; a first resistor section that makes a connection between the first positive-phase voltage transmission line and the second positive-phase voltage transmission line; and a second resistor section that makes a connection between the first reversed-phase voltage transmission line and the second reversed-phase voltage transmission line.

### CROSS REFERENCE TO RELATED APPLICATIONS

This application claims the benefit of Japanese Priority Patent Application JP 2013-060154 filed on Mar. 22, 2013, the entire contents of which are incorporated herein by reference.

### BACKGROUND

The present technology relates to a transconductance adjusting circuit, a filter circuit that includes such a transconductance adjusting circuit, and an electronic apparatus that includes such a filter circuit.

Typically, an automatic Gm adjusting circuit is known that automatically adjusts a Gm value of a transconductance amplifier (hereinafter referred to as a “Gm amplifier”) that may be included in various filter circuits (for example, see Japanese Unexamined Patent Application Publication No. 2005-348109, non-patent literature: Tien-Yu Lo and Chung-Chih Hung, “1V CMOS Gm-C Filters”, Springer, pp. 127-130, and the like).

With reference to FIG. 6 and FIG. 7, the description is provided on a currently-available automatic Gm adjusting circuit. FIG. 6 is a circuit diagram showing a configuration of an automatic Gm adjusting circuit that is disclosed in the above-described non-patent literature, and FIG. 7 is a circuit diagram showing an internal configuration of a Gm amplifier that is included in the automatic Gm adjusting circuit illustrated in FIG. 6.

An automatic Gm adjusting circuit 1 shown in FIG. 6 includes a Gm amplifier 2, a resistor 3, an integrating circuit 4, and a constant-voltage source 5. As shown in FIG. 7, the Gm amplifier 2 includes P-channel MOS transistors (hereinafter referred to as “pFETs”) 2a and 2b, as well as N-channel MOS transistors (hereinafter referred to as “nFETs”) 2c to 2g.

An inverting input terminal of the Gm amplifier 2 is grounded, and a non-inverting input terminal thereof is connected with a negative electrode of the constant-voltage source 5. A positive electrode of the constant-voltage source 5 is grounded. Therefore, a voltage Vin that is provided from the constant-voltage source 5 is applied to the non-inverting input terminal of the Gm amplifier 2.

The resistor 3 makes a connection between the non-inverting input terminal and an output terminal of the Gm amplifier 2. With such a configuration, a current Iout flows from the output terminal to the input terminal of the Gm amplifier 2, which generates a voltage Vsc in accordance with a resistance Rsc of the resistor 3 and the current Iout as represented in Expression (1) below between the output terminal and the input terminal of the Gm amplifier 2.

[Expression 1]

Iout=Vsc/Rsc (1)

Further, the integrating circuit 4 has a function of holding the output voltage of the Gm amplifier 2 at a ground potential. More specifically, the integrating circuit 4 compares the output voltage of the Gm amplifier 2 with a ground potential, and inputs a control voltage Vgm for matching these voltages to the Gm amplifier 2. This controls the output voltage of the Gm amplifier 2 to be equal to a ground potential.

As a result, the voltage Vsc that is generated between the output terminal and the non-inverting input terminal of the Gm amplifier 2 is made equal to the voltage Vin that is applied between the inverting input terminal and the non-inverting input terminal of the Gm amplifier 2 as represented in Expression (2) below.

[Expression 2]

Vin=Vsc (2)

By satisfying Expression (2), it is possible to represent a Gm value of the Gm amplifier 2 using the resistance Rsc of the resistor 3. In other words, the Gm value of the Gm amplifier 2 is represented by Expression (3) below using the input voltage Vin and the output current Iout of the Gm amplifier 2, and thus Expression (4) below is established by substituting the above Expressions (1) and (2) for Expression (3) below.

[Expression 3]

Gm=Iout/Vin (3)

[Expression 4]

Gm=1/Rsc (4)

Expression (4) indicates that it is possible to adjust the Gm value of the Gm amplifier 2 at a desired value in a manner of adjusting only the resistance of the resistor 3 by fixing the output potential of the Gm amplifier 2 at the ground potential while connecting the output terminal and the non-inverting input terminal of the Gm amplifier 2 via the resistor 3.

However, it is likely that the resistance of the resistor 3 will have a variation. As a matter of course, there is no variation in the output current Tout due to the absence of an absolute variation in the resistance if the resistor is an ideal resistor, and it is possible to adjust the Gm value at a desired value in a case of a reference resistor in which the resistor 3 is mounted outside an IC. However, it is difficult to avoid occurrence of the absolute variation in the resistance of the resistor 3 that is provided inside an IC.

FIG. 8 is an example of a circuit configuration of an automatic Gm adjusting circuit 1′ that cancels the absolute variation in the resistance of the resistor 3. In this drawing, any component parts essentially same as those in FIG. 7 are denoted with the same reference numerals. In the automatic Gm adjusting circuit 1′ shown in FIG. 8, a switched capacitor circuit 6 is provided instead of the resistor 3.

The switched capacitor circuit 6 includes a capacitor 6a with capacitance Csc, and four switches 6b to 6e. An on/off state of the switches 6b and 6c is controlled with a clock signal at frequency Fref1, while an on/off state of the switches 6d and 6e is controlled with a clock signal at frequency Fref2. The frequencies Fref1 and Fref2 are identical to each other in a timing cycle, and are opposite to each other in a phase. A resistance Rsc of the switched capacitor circuit 6 is represented by Expression (5) below. Further, a Gm value of a Gm amplifier 2′ shown in FIG. 8 is represented by Expression (6) below.

$$\begin{matrix}[ Expression 5 ] & \\ Rsc = \frac{1}{C s c \times Fref} & ( 5 ) \\ [ Expression 6 ] & \\ Gm = \frac{Iout}{Vin} = \frac{Fref \times C s c \times Vsc}{Vin} & ( 6 )\end{matrix}$$

It is to be noted that, also in the automatic Gm adjusting circuit 1′ shown in FIG. 8, there is still left an influence of a variation in the capacitance of the capacitor 6a. In a Gm-C filter, however, a capacitor is arranged at a main circuit side. Configuration of the capacitor at the main circuit side and the capacitor 6a using capacitors with similar variations makes it possible to cancel a variation in the Gm value that is caused by variations in the capacitance of the capacitors.

FIG. 9 is an example of a Gm-C filter using a Gm amplifier. A Gm-C filter circuit 7 shown in this drawing includes a Gm amplifier 7a and a capacitor 7b. An output voltage Vb of the Gm amplifier 7a is represented as indicated in Expression (7) below. In Expression (7) below, Va is an input voltage of the Gm amplifier 7a, Gm is a Gm value of the Gm amplifier 7a, and C is a capacitance of the capacitor 7a.

$$\begin{matrix}[ Expression 7 ] & \\ Vb = \frac{Gm}{sC} Va & ( 7 )\end{matrix}$$

Here, when the Gm value of the Gm amplifier 7a is adjusted using a voltage Vgm of the automatic Gm adjusting circuit 1′ shown in FIG. 8, the above Expression (7) is represented as indicated in Expression (8) below. In other words, it is found that the Csc is cancelled with the C, which allows an influence of a variation in the capacitance of the capacitor 6a to be eliminated.

$$\begin{matrix}[ Expression 8 ] & \\ \begin{matrix}Vb = \frac{Fref \times C s c \times Vsc}{Vin} \frac{1}{sC} Va \\ = \frac{Fref \times Vsc}{s \times Vin} Va\end{matrix} & ( 8 )\end{matrix}$$

### SUMMARY

However, the existing automatic Gm adjusting circuits 1 and 1′ as described above are disadvantageous in that an error current occurs in an output current. If an error current occurs in an output current, the control voltage Vgm is shifted, which makes it difficult to adjust a Gm value of a Gm amplifier at a desired value.

It is desirable to provide a technology that suppresses an error current arising in an output current of a Gm amplifier to improve the accuracy in the adjustment of a Gm value as compared with an existing method.

According to an embodiment of the present technology, there is provided a transconductance adjusting circuit, including: a voltage generating section configured to generate a first differential voltage; a first transconductance amplifier configured to receive the first differential voltage through a first positive-phase voltage transmission line and a first reversed-phase voltage transmission line, and output a second differential voltage through a second positive-phase voltage transmission line and a second reversed-phase voltage transmission line; a first control section configured to receive the second differential voltage and supply a feedback of a first control voltage to the first transconductance amplifier; a second control section configured to receive the second differential voltage and supply a feedback of a second control voltage to the first transconductance amplifier; a first resistor section that makes a connection between the first positive-phase voltage transmission line and the second positive-phase voltage transmission line; and a second resistor section that makes a connection between the first reversed-phase voltage transmission line and the second reversed-phase voltage transmission line.

According to an embodiment of the present technology, there is provided a filter circuit, including: a transconductance adjusting circuit, the transconductance adjusting circuit including a voltage generating section configured to generate a first differential voltage, a first transconductance amplifier configured to receive the first differential voltage through a first positive-phase voltage transmission line and a first reversed-phase voltage transmission line, and output a second differential voltage through a second positive-phase voltage transmission line and a second reversed-phase voltage transmission line, a first control section configured to receive the second differential voltage and supply a feedback of a first control voltage to the first transconductance amplifier, a second control section configured to receive the second differential voltage and supply a feedback of a second control voltage to the first transconductance amplifier, a first resistor section that makes a connection between the first positive-phase voltage transmission line and the second positive-phase voltage transmission line, and a second resistor section that makes a connection between the first reversed-phase voltage transmission line and the second reversed-phase voltage transmission line; and a second transconductance amplifier configured to received the first control voltage from the first control section.

According to an embodiment of the present technology, there is provided an electronic apparatus provided with a filter circuit, the filter circuit including: a transconductance adjusting circuit, the transconductance adjusting circuit including a voltage generating section configured to generate a first differential voltage, a first transconductance amplifier configured to receive the first differential voltage through a first positive-phase voltage transmission line and a first reversed-phase voltage transmission line, and output a second differential voltage through a second positive-phase voltage transmission line and a second reversed-phase voltage transmission line, a first control section configured to receive the second differential voltage and supply a feedback of a first control voltage to the first transconductance amplifier, a second control section configured to receive the second differential voltage and supply a feedback of a second control voltage to the first transconductance amplifier, a first resistor section that makes a connection between the first positive-phase voltage transmission line and the second positive-phase voltage transmission line, and a second resistor section that makes a connection between the first reversed-phase voltage transmission line and the second reversed-phase voltage transmission line; and a second transconductance amplifier configured to received the first control voltage from the first control section.

According to the above-described embodiments of the present technology, it is possible to suppress an error current arising in an output current of a Gm amplifier to improve the accuracy in the adjustment of a Gm value as compared with an existing method.

It is to be understood that both the foregoing general description and the following detailed description are exemplary, and are intended to provide further explanation of the technology as claimed.

### BRIEF DESCRIPTION OF THE DRAWINGS

The accompanying drawings are included to provide a further understanding of the present disclosure, and are incorporated in and constitute a part of this specification. The drawings illustrate embodiments and, together with the specification, serve to explain the principles of the present technology.

FIG. 1 is a schematic block diagram for explaining a Gm adjusting circuit according to an embodiment of the present technology.

FIG. 2 is a circuit diagram showing an internal configuration of a Gm amplifier in use for the Gm adjusting circuit according to an embodiment of the present technology.

FIG. 3 is a circuit diagram showing an example of resistor sections.

FIG. 4 is a circuit diagram showing an example of a filter circuit according to a second embodiment of the present technology.

FIG. 5 is a circuit diagram showing an example of a Gm-C filter circuit.

FIG. 6 is a schematic block diagram for explaining an existing Gm adjusting circuit.

FIG. 7 is a circuit diagram showing an internal configuration of a Gm amplifier in use for the existing Gm adjusting circuit.

FIG. 8 is a circuit diagram showing an example of a circuit configuration for cancelling an absolute variation in the resistance of a resistor.

FIG. 9 is a circuit diagram showing an example of a Gm-C filter circuit using a Gm amplifier.

### DETAILED DESCRIPTION

Hereinafter, some embodiments of the present technology are described in the order given below.

### (1) First Embodiment

### (2) Second Embodiment

### (3) Summary

### (1) First Embodiment

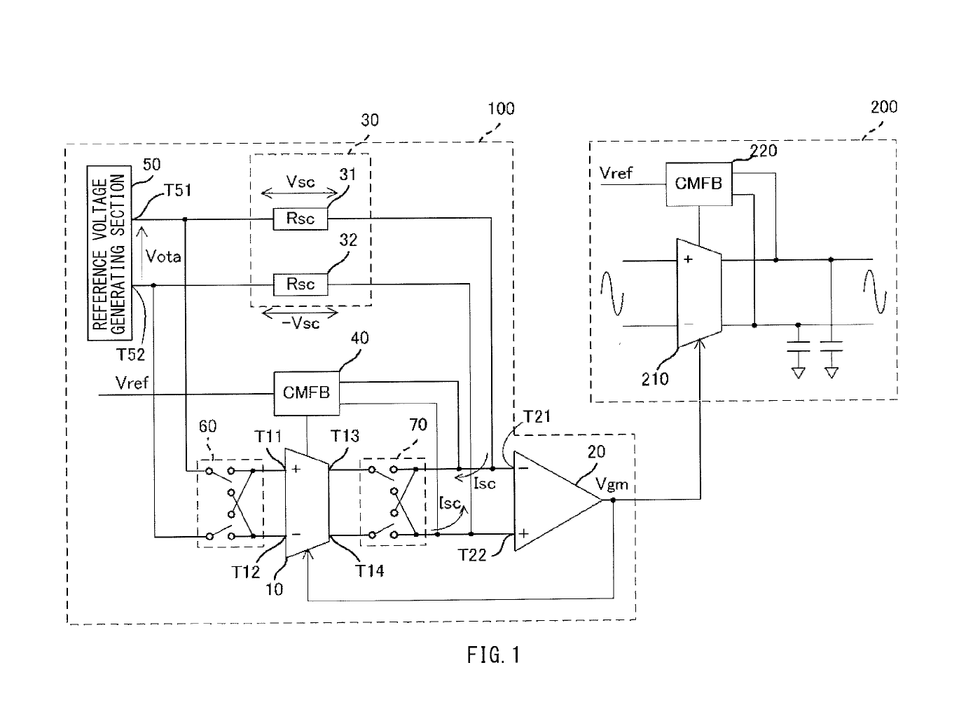

FIG. 1 is a schematic block diagram for explaining a Gm adjusting circuit 100 according to an embodiment of the present technology. The Gm adjusting circuit 100 shown in this drawing includes a Gm amplifier 10 working as a first transconductance amplifier, and a Gm value control circuit 20. The Gm value control circuit 20 generates a control voltage Vgm for controlling a Gm value of the Gm amplifier 10. Subsequently, the Gm value control circuit 20 inputs the control voltage Vgm to the Gm amplifier 10, and outputs this control voltage to a practical usage circuit section 200 at the same time. This control voltage Vgm is intended to accurately adjust the Gm value of the Gm amplifier 10.

The practical usage circuit section 200 includes a Gm amplifier 210 working as a second transconductance amplifier that is manufactured to have the same characteristics with similarly the same manufacturing process as the Gm amplifier 10. The above-described control voltage Vgm is input to the Gm amplifier 210 as a control voltage for controlling the Gm value. Therefore, as with the Gm amplifier 10, a Gm value of the Gm amplifier 210 is also controlled accurately to be adjusted at a desired value.

It is to be noted that the Gm amplifier 210 in the practical usage circuit section 200 also includes a CMFB 220 similar to a CMFB 40 for controlling a common voltage of the Gm amplifier 10 to be hereinafter described, and this CMFB 220 inputs a control voltage to the Gm amplifier 210 for feedback control to ensure that a common voltage of the Gm amplifier 210 comes close to a reference voltage Vref. In this embodiment of the present technology, such a control voltage configures a third control voltage, and the CMFB 220 configures a third control section.

Hereinafter, the description is provided on the Gm adjusting circuit 100.

The Gm adjusting circuit 100 includes the Gm amplifier 10, the Gm value control circuit 20 as a first control section, a reference voltage generating section 50 as a voltage generating section, a common feedback circuit 40 (CMFB 40) as a second control section, an input-side switching circuit 60 as a first switch section, an output-side switching circuit 70 as a second switch section, a first resistor section 31, and a second resistor section 32.

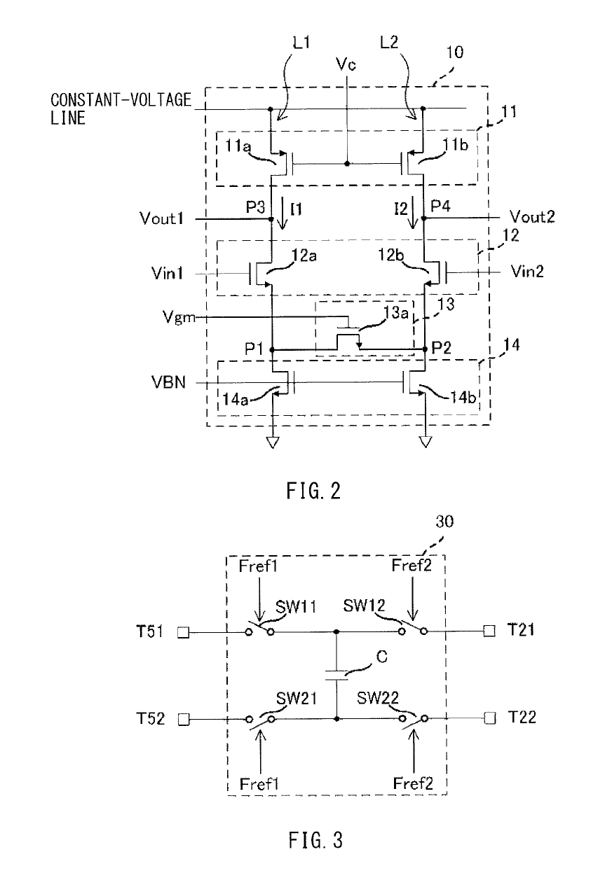

FIG. 2 is a circuit diagram showing an example of an internal configuration of the Gm amplifier 10. The Gm amplifier 10 shown in this drawing includes a first current line L1 as a first line and a second current line L2 as a second line, as well as a first current pair 11 that is arranged at the upstream side of the current lines, a differential pair 12, an inter-line current control section 13, and a second current pair 14 that is arranged at the downstream side of the current lines. The first current line L1 and the second current line L2 make a connection between a power supply voltage and a ground.

The first current pair 11 has a pFET 11a as a first transistor that operates as a current source and a pFET 11b as a second transistor that operates as a current source. The pFET 11a has a source-drain region that is interposed on the current line L1, while the pFET 11b has a source-drain region that is interposed on the current line L2. The pFET 11a and the pFET 11b are designed to ensure that the characteristics thereof are matched to each other, and a same control voltage Vc is input to a gate as a control terminal of each of these pFETs. This control voltage Vc configures a second control voltage in this embodiment of the present technology.

As a result, ideally in design, an equivalent current flows between a source and a drain of each of the pFET 11a and the pFET 11b.

The differential pair 12 has an nFET 12a as a third transistor and an nFET 12b as a fourth transistor. It is to be noted that the differential pair 12 is not limited to an nFET pair, but may be configured of a pFET pair alternatively. The nFET 12a has a source-drain region that is interposed on the current line L1, while the nFET 12b has a source-drain region that is interposed on the current line L2. The nFET 12a and the nFET 12b are designed to ensure that the characteristics thereof are matched to each other. An input voltage Vin1 is input to a gate as a control terminal of the nFET 12a, and an input voltage Vin2 is input to a gate as a control terminal of the nFET 12b.

Consequently, a current I1 in accordance with the input voltage Vin1 is generated on the current line L1, and a current I2 in accordance with the input voltage Vin2 is generated on the current line L2.

The inter-line current control section 13 includes an nFET 13a as a fifth transistor. The nFET 13a makes a connection between a point P1 on the current line L1 and a point P2 on the current line L2 at a source-drain region thereof. The control voltage Vgm as a first control voltage is input to a gate as a control terminal of the nFET 13a.

In such a manner, a degree of conduction between the point P1 and the point P2 is controlled to the extent depending on the control voltage Vgm, thereby controlling the amount of a current flowing between the point P1 and the point P2, that is, a current flowing between the current line L1 and the current line L2.

The second current pair 14 has an nFET 14a that operates as a current source and an nFET 14b that operates as a current source. The nFET 14a has a source-drain region that is interposed on the current line L1, while the nFET 14b has a source-drain region that is interposed on the current line L2. The nFET 14a and the nFET 14b are designed to ensure that the characteristics thereof are matched to each other, and a same constant voltage VBN is input to a gate of each of these nFETs.

As a result, ideally in design, an equivalent current flows between a source and a drain of each of the nFET 14a and the nFET 14b.

Each of the FETs is arranged on the current line L1 and the current line L2 in the following manner. On the current line L1, the pFET 11a, the nFET 12a, and the nFET 14a are arranged in this order from the upstream side. On the current line L2, the pFET 11b, the nFET 12b, and the nFET 14b are arranged in this order from the upstream side.

The point P1 is located between the nFET 12a and the nFET 14a on the current line L1, and the point P2 is located between the nFET 12b and the nFET 14b on the current line L2.

On the other hand, an output voltage Vout1 is output from a point P3, and an output voltage Vout2 is output from a point P4. The point P3 is located between the pFET 11a and the nFET 12a on the current line L1, and the point P4 is located between the pFET 11b and the nFET 12b on the current line L2.

The reference voltage generating section 50 generates a reference voltage difference Vota between an output terminal T51 and an output terminal T52, and applies this reference voltage difference Vota between two input terminals T11 and T12 of the Gm amplifier 10. Two input terminals T11 and T12 as described above correspond to the gate of the nFET 12a and the gate of the nFET 12b, respectively that are described previously, and a voltage difference between the input voltage Vin1 and the input voltage Vin2 corresponds to the reference voltage difference Vota.

The Gm value control circuit 20 has a configuration of a comparator circuit that outputs a result of comparing two input voltages. For example, the Gm value control circuit 20 may be configured of a comparator using an operational amplifier and the like, and an output voltage Vout1 that is output from the Gm amplifier 10 is input to one of an inverting input terminal and a non-inverting input terminal, while an output voltage Vout2 that is output from the Gm amplifier 10 is input to the other.

Subsequently, the Gm value control circuit 20 gives a feedback of a voltage in accordance with a difference between the output voltage Vout1 and the output voltage Vout2 to the Gm amplifier 10 as the control voltage Vgm. With such a feedback control, the Gm amplifier 10 is controlled in such a manner that the output voltage Vout1 and the output voltage Vout2 become equal to each other in the potential, that is, a difference voltage (=Vout1−Vout2) approaches zero.

In such a manner, the Vgm value is adjusted to achieve the desired Gm value.

Further, by configuring the input/output of the Gm amplifier 10 in the Gm adjusting circuit 100 in a differential manner, one side of a differential output of the Gm amplifier 10 is not put in a floating state in a case where the input/output of the Gm amplifier 210 in the practical usage circuit 200 are configured in a differential manner (configuration in which a differential signal is input, and a differential signal is output), and thus a system offset does not occur. This suppresses at least a part of an error current arising at outputs of the Gm amplifiers 2 and 2′ in the above-described existing automatic Gm adjusting circuit 1, which makes it possible to improve the accuracy of adjusting the Gm value.

A common voltage (=(Vout1+Vout2)/2) of the output voltage Vout1 and the output voltage Vout2 that are output from the Gm amplifier 10 is input to the CMFB circuit 40, which controls the Gm amplifier 10 to ensure that this common voltage comes close to the reference voltage Vref.

More specifically, the CMFB circuit 40 inputs a voltage in accordance with a difference between the common voltage and the reference voltage Vref to the Gm amplifier 10 as a control voltage Vc.

As a result, the common voltage of the output voltage Vout1 and the output voltage Vout2 that are output from the Gm amplifier 10 is stabilized to be maintained at the reference voltage Vref.

The first resistor section 31 connects a positive-phase voltage transmission line of a differential voltage that is input to the Gm amplifier 10 with a positive-phase voltage transmission line of a differential voltage that is output from the Gm amplifier 10 by making a connection between the output terminal T51 of the reference voltage generating section 50 and an input terminal T21 of the Gm value control circuit 20 (an inverting input terminal in the case of a comparator).

The second resistor section 32 connects a reversed-phase voltage transmission line of a differential voltage that is input to the Gm amplifier 10 with a reversed-phase voltage transmission line of a differential voltage that is output from the Gm amplifier 10 by making a connection between the output terminal T52 of the reference voltage generating section 50 and an input terminal T22 of the Gm value control circuit 20 (a non-inverting input terminal in the case of a comparator).

In this embodiment of the present technology, each of the first resistor section 31 and the second resistor section 32 is configured of a switched capacitor circuit.

FIG. 3 is a circuit diagram showing an example of a switched capacitor circuit as a resistor section 30 that configures both of the first resistor section 31 and the second resistor section 32.

The switched capacitor circuit shown in this drawing has four switch circuits SW11, SW12, SW21, and SW22, as well as a capacitor C. The switch circuits SW11 and SW12 make a series connection between the output terminal T51 and the input terminal T21, and the switch circuits SW21 and SW22 make a series connection between the output terminal T52 and the input terminal T22. The capacitor C makes a connection between a connecting point of the switch circuits SW11 and SW12 and a connecting point of the switch circuits SW21 and SW22.

A control signal Fref1 for a cyclic on/off control is input to the switch circuit SW11 and the switch circuit SW21, and a control signal Fref2 for a cyclic on/off control is input to the switch circuit SW12 and the switch circuit SW22. The control signals Fref1 and Fref2 are signals that are identical to each other in a timing cycle and are opposite to each other in a phase.

In such a manner, by adopting the switched capacitor circuit for the resistor section 30, as with the automatic Gm adjusting circuit described in the above-described non-patent literature as mentioned previously, it is possible to prevent a variation in the Gm value that is caused by an absolute variation in the resistance of the first resistor section 31 and the second resistor section 32. Further, if the capacitor to be used at the side of the practical usage circuit 200 and the capacitor C are configured of capacitors having similar variations in the resistance, this makes it possible to cancel a variation in the Gm value that is caused by a variation in the resistance of the capacitors as with the above-described existing technology.

Further, like the switched capacitor circuit shown in FIG. 3, by adopting a configuration of making a connection between the lines using the capacitor C, it is possible to reduce the number of devices as compared with the configuration of arranging capacitors on the lines as described in the above non-patent literature. Obviously, as mentioned in such non-patent literature, the adoption of a configuration where a switched capacitor circuit is arranged for each line also allows the present technology to be achieved.

On this occasion, a current Isc flowing between the output terminals of the Gm amplifier 10 is determined by the following Expression (9).

[Expression 9]

Isc=Rsc×Vsc (9)

Further, a Gm value of the Gm amplifier 10 is represented by the following Expression (10).

$$\begin{matrix}[ Expression 10 ] & \\ Gm = \frac{Isc}{Vota} = \frac{Rsc \times Vsc}{Vota} & ( 10 )\end{matrix}$$

Here, Vota is a constant voltage, and Rsc is a fixed value as well. An output voltage of the Gm amplifier 10 is controlled by the CMFB circuit 40 to be equal to Vref, and thus the voltage Vsc (or −Vsc) that is applied to the first resistor section 31 and the second resistor section 32 becomes constant as well.

This makes it possible to accurately control the Gm value of the Gm amplifier 10 to be a constant value without being influenced by relative variations in internal elements of the Gm amplifier 10. Also for the Gm amplifier 210 to which the control voltage Vgm for adjusting the Gm value of the Gm amplifier 10 is applied as an input, the Gm value thereof is accurately adjusted to be a constant value in the same manner.

The input-side switching circuit 60 is provided between input terminals T11 and T12 of the Gm amplifier 10 and output terminals T51 and T52 of the reference voltage generating section 50. The output-side switching circuit 70 is provided between output terminals T13 and T14 of the Gm amplifier 10 and input terminals T21 and T22 of the Gm value control circuit 20. In this embodiment of the present technology, the input terminals T11 and T12 correspond to a specific but not limitative example of “two input sections”, and the output terminals T13 and T14 correspond to a specific but not limitative example of “two output sections”.

The input-side switching circuit 60 carries out chopper operation for switching a connection relationship between the input terminals T11 and T12 and the output terminals T51 and T52 at a constant timing cycle f alternately. This chopper operation may be controlled by, for example, a periodic signal that is externally input to the input-side switching circuit 60.

More specifically, the input-side switching circuit 60 makes a periodic switching between a first connection state of connecting the input terminal T11 with the output terminal T51, while connecting the input terminal T12 with the output terminal T52 and a second connection state of connecting the input terminal T11 with the output terminal T52, while connecting the input terminal T12 with the output terminal T51.

The output-side switching circuit 70 carries out chopper operation for switching a connection relationship between the output terminals T13 and T14 and the input terminals T21 and T22 at a constant timing cycle f alternately in synchronization with the chopper operation of the input-side switching circuit 60. Also, this chopper operation may be controlled by, for example, a periodic signal that is externally input to the output-side switching circuit 70.

More specifically, the output-side switching circuit 70 makes a periodic switching between a third connection state of connecting the output terminal T13 with the input terminal T21, while connecting the output terminal T14 with the input terminal T21 and a fourth connection state of connecting the output terminal T13 with the input terminal T22, while connecting the output terminal T14 with the input terminal T21.

Further, each of the connection relationships is achieved in such a manner that the first connection relationship is synchronized with the third connection relationship and the second connection relationship is synchronized with the fourth connection relationship. In other words, a positive phase and a reversed phase in a first differential voltage that is input to the Gm amplifier 10 and a second differential voltage that is output from the Gm amplifier 10 are switched on a periodic basis.

Here, as shown in FIG. 2, in the Gm amplifier 10, internal elements are arranged in a mirror-symmetric manner (bilaterally-symmetric manner in FIG. 2), and thus the internal elements are used in a well-balanced manner bilaterally in the positive-phase voltage inputs/outputs and the reversed-phase voltage inputs/outputs of the Gm amplifier 10, resulting in right-and-left variations in the internal elements being averaged.

This alleviates an influence of relative variations in the internal elements of the Gm amplifier 10, which makes it possible to reduce an influence of an error current in the adjustment of the Gm value.

### (2) Second Embodiment

Next, the description is provided on a filter circuit that includes the above-described Gm adjusting circuit 100 and practical usage circuit 200.

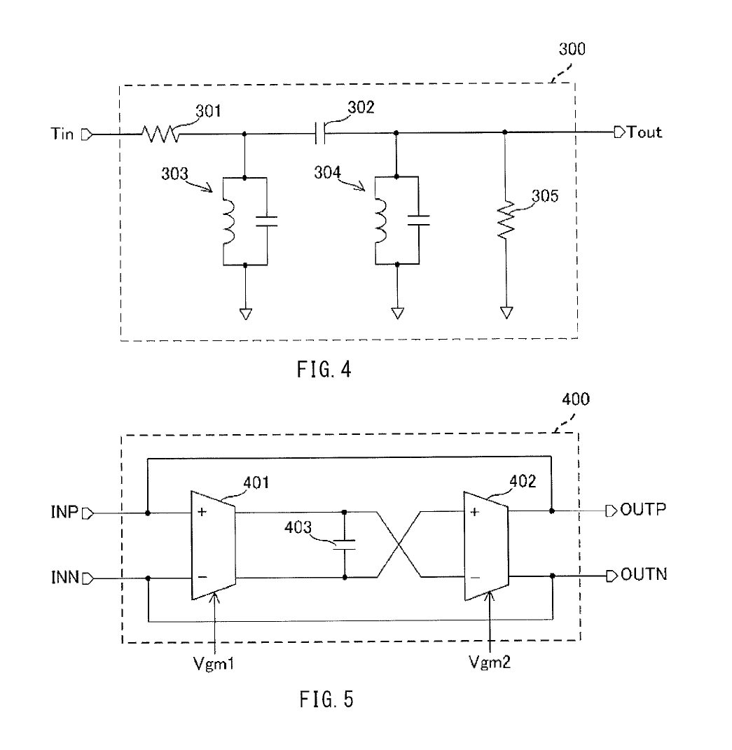

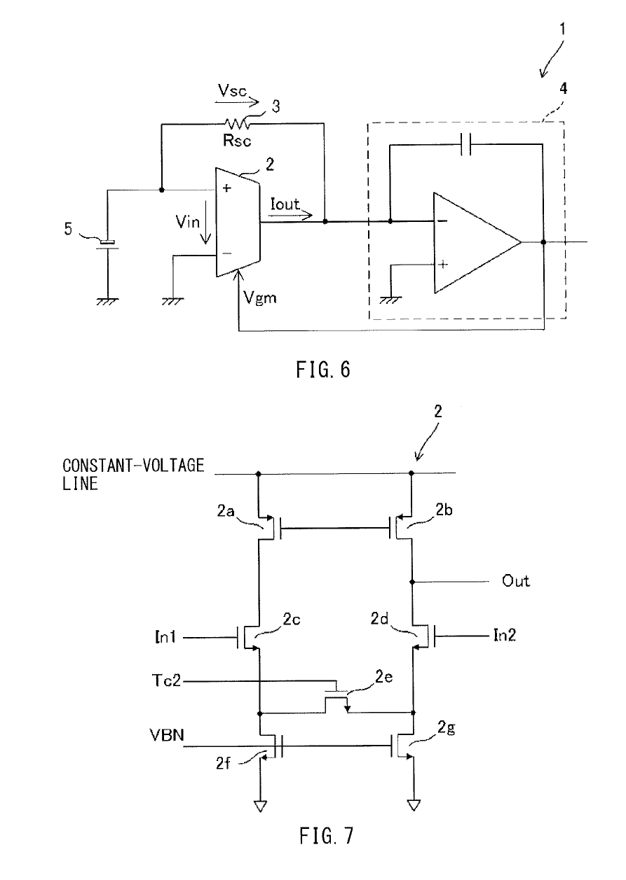

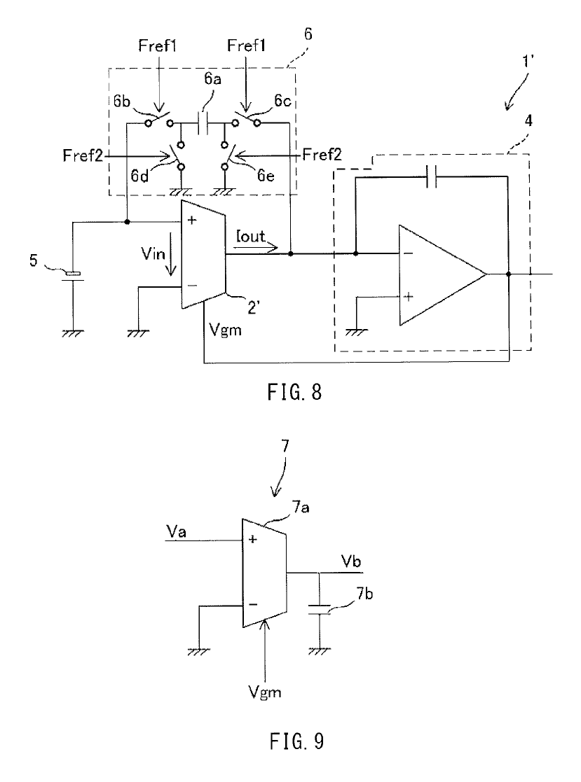

FIG. 4 is a circuit diagram showing an example of a filter circuit according to this embodiment of the present technology. A filter circuit 300 shown in this drawing is a second-order double-tuned filter circuit adopting a C-coupling method of coupling two transformers using a capacitor.

The filter circuit 300 includes a resistor 301, a capacitor 302, parallel resonant circuits 303 and 304 each of which is configured of a transformer (inductor) and a capacitor, and a resistor 305. The resistor 301 and the capacitor 302 are connected in series, and a connection is made between an input terminal Tin and an output terminal Tout with the resistor 301 directed toward the input terminal Tin side and with the capacitor 302 directed toward the output terminal Tout side.

A first end of the parallel resonant circuit 303 is connected between the resistor 301 and the capacitor 302, and a second end thereof is grounded. A first end of the parallel resonant circuit 304 is connected between the capacitor 302 and the output terminal Tout, and a second end thereof is grounded. Also, a first end of the resistor 305 is connected between the capacitor 302 and the output terminal Tout, and a second end thereof is grounded. When such a filter circuit is formed on a semiconductor integrated circuit board, an inductor section is configured of a Gm-C filter as a common practice.

FIG. 5 is a circuit diagram showing an example of a Gm-C filter circuit. A Gm-C filter circuit 400 shown in this drawing includes Gm amplifiers 401 and 402 as well as a capacitor 403. An output terminal of the Gm amplifier 401 and an input terminal of the Gm amplifier 402 are cross-wired with each other. An input terminal of the Gm amplifier 401 and an output terminal of the Gm amplifier 402 are straight-wired with each other.

As with the Gm amplifier 210 according to the above-described first embodiment of the present technology, a Gm adjusting circuit similar to the Gm adjusting circuit 100 is connected with each of the Gm amplifiers 401 and 402. Each of these Gm adjusting circuits generates control voltages Vgm1 and Vgm2 for achieving desired Gm values in the Gm amplifiers 401 and 402 respectively, and inputs such control voltages to control terminals of the Gm amplifiers 401 and 402. This makes it possible to accurately achieve the desired Gm values in the Gm amplifiers 401 and 402, which allows the accuracy of the filter circuit to be further improved as compared with an existing manner.

It is to be noted that the present technology is also achievable as a radio receiver including various filter circuits having Gm amplifiers, such as the Gm-C filter circuit 400 according to this embodiment of the present technology. Further, it goes without saying that the present technology is not limited to the radio receiver, but is achievable as various electronic apparatuses as well.

### (3) Summary

As described thus far, according to the above-described embodiments of the present technology, there is provided the Gm adjusting circuit 100 including: the voltage generating section 50 that generates the first differential voltage; the Gm amplifier 10 to which the first differential voltage is input and which outputs the second differential voltage; the Gm value control circuit 20 to which the second differential voltage is input and which gives a feedback of the control voltage Vgm to the Gm amplifier 10; the CMFB circuit 40 to which the second differential voltage is input and which gives a feedback of the control voltage Vc to the Gm amplifier 10; the first resistor section 31 that makes a connection between the positive-phase voltage transmission line of the first differential voltage and the positive-phase voltage transmission line of the second differential voltage; and the second resistor section 32 that makes a connection between the reversed-phase voltage transmission line of the first differential voltage and the reversed-phase voltage transmission line of the second differential voltage. In this Gm adjusting circuit 100, it is possible to suppress an error current arising in an output current of the Gm amplifier 10 for further improving the accuracy in the adjustment of the Gm value as compared with an existing technology.

It is to be noted that the present technology is not limited to the above-described embodiments and modification examples, but may also involve configurations that replace each of the configurations disclosed in the above-described embodiments and modification examples with one other or change a combination thereof, or configurations that replace each of the configurations disclosed in a known technology as well as the above-described embodiments and modification examples with one other or change a combination thereof, and the like. Further, the technical scope of the present technology is not limited to the above-described embodiments, but covers elements and matters described in the appended claims and the equivalents thereof.

It is possible to achieve at least the following configurations from the above-described example embodiments of the disclosure.

(A) A transconductance adjusting circuit, including:

a voltage generating section configured to generate a first differential voltage;

a first transconductance amplifier configured to receive the first differential voltage through a first positive-phase voltage transmission line and a first reversed-phase voltage transmission line, and output a second differential voltage through a second positive-phase voltage transmission line and a second reversed-phase voltage transmission line;

a first control section configured to receive the second differential voltage and supply a feedback of a first control voltage to the first transconductance amplifier;

a second control section configured to receive the second differential voltage and supply a feedback of a second control voltage to the first transconductance amplifier;

a first resistor section that makes a connection between the first positive-phase voltage transmission line and the second positive-phase voltage transmission line; and

a second resistor section that makes a connection between the first reversed-phase voltage transmission line and the second reversed-phase voltage transmission line.

(B) The transconductance adjusting circuit according to (A), further including:

a first switching section configured to switch an input destination of a positive-phase voltage and a reversed-phase voltage of the first differential voltage at a predetermined cycle between two input sections of the first transconductance amplifier; and

a second switching section configured to switch an output destination of a positive-phase voltage and a reversed-phase voltage of the second differential voltage in synchronization with a switching cycle of the first switching section between two output sections of the first transconductance amplifier.

(C) The transconductance adjusting circuit according to (A) or (B), wherein the first resistor section and the second resistor section are each a switched capacitor circuit.
(D) The transconductance adjusting circuit according to any one of (A) to (C), wherein the first transconductance amplifier includes:

a first line that makes a connection between a power supply and a ground;

a second line that makes a connection between the power supply and the ground;

a current pair having a first transistor and a second transistor;

a differential pair having a third transistor and a fourth transistor; and

a fifth transistor that makes a connection between the first line and the second line at downstream of the differential pair, and

wherein the first transistor is provided on the first line,

the second transistor is provided on the second line,

the third transistor is provided at downstream of the first transistor on the first line,

the fourth transistor is provided at downstream of the second transistor on the second line,

the second control voltage is supplied to a control terminal of the first transistor and a control terminal of the second transistor,

the first differential voltage is supplied between a control terminal of the third transistor and a control terminal of the fourth transistor,

a voltage difference between a first voltage and a second voltage is output as the second differential voltage, the first voltage being generated at a node between the first transistor and the third transistor on the first line, the second voltage being generated at a node between the second transistor and the fourth transistor on the second line, and

the first control voltage is supplied to a control terminal of the fifth transistor.

(E) A filter circuit, including:

a transconductance adjusting circuit, the transconductance adjusting circuit including
a voltage generating section configured to generate a first differential voltage,
a first transconductance amplifier configured to receive the first differential voltage through a first positive-phase voltage transmission line and a first reversed-phase voltage transmission line, and output a second differential voltage through a second positive-phase voltage transmission line and a second reversed-phase voltage transmission line,
a first control section configured to receive the second differential voltage and supply a feedback of a first control voltage to the first transconductance amplifier,
a second control section configured to receive the second differential voltage and supply a feedback of a second control voltage to the first transconductance amplifier,
a first resistor section that makes a connection between the first positive-phase voltage transmission line and the second positive-phase voltage transmission line, and
a second resistor section that makes a connection between the first reversed-phase voltage transmission line and the second reversed-phase voltage transmission line; and

a second transconductance amplifier configured to received the first control voltage from the first control section.

(F) The filter circuit according to (E), wherein the second transconductance amplifier receives a differential signal and outputs a differential signal.
(G) The filter circuit according to (E) or (F), further including a third control section configured to receive a differential signal output from the second transconductance amplifier and supply a feedback of a third control voltage to the second transconductance amplifier.
(H) An electronic apparatus provided with a filter circuit, the filter circuit including:

a transconductance adjusting circuit, the transconductance adjusting circuit including
a voltage generating section configured to generate a first differential voltage,
a first transconductance amplifier configured to receive the first differential voltage through a first positive-phase voltage transmission line and a first reversed-phase voltage transmission line, and output a second differential voltage through a second positive-phase voltage transmission line and a second reversed-phase voltage transmission line,
a first control section configured to receive the second differential voltage and supply a feedback of a first control voltage to the first transconductance amplifier,
a second control section configured to receive the second differential voltage and supply a feedback of a second control voltage to the first transconductance amplifier,
a first resistor section that makes a connection between the first positive-phase voltage transmission line and the second positive-phase voltage transmission line, and
a second resistor section that makes a connection between the first reversed-phase voltage transmission line and the second reversed-phase voltage transmission line; and

a second transconductance amplifier configured to received the first control voltage from the first control section.

It should be understood by those skilled in the art that various modifications, combinations, sub-combinations and alterations may occur depending on design requirements and other factors insofar as they are within the scope of the appended claims or the equivalents thereof.

What is claimed is:

1. A transconductance adjusting circuit, comprising:
a voltage generating section configured to generate a first differential voltage;
a first transconductance amplifier configured to receive the first differential voltage through a first positive-phase voltage transmission line and a first reversed-phase voltage transmission line, and output a second differential voltage through a second positive-phase voltage transmission line and a second reversed-phase voltage transmission line;
a first control section configured to receive the second differential voltage and supply a feedback of a first control voltage to the first transconductance amplifier;
a second control section configured to receive the second differential voltage and supply a feedback of a second control voltage to the first transconductance amplifier;
a first resistor section that makes a connection between the first positive-phase voltage transmission line and the second positive-phase voltage transmission line; and
a second resistor section that makes a connection between the first reversed-phase voltage transmission line and the second reversed-phase voltage transmission line.

2. The transconductance adjusting circuit according to claim 1, further comprising:
a first switching section configured to switch an input destination of a positive-phase voltage and a reversed-phase voltage of the first differential voltage at a predetermined cycle between two input sections of the first transconductance amplifier; and
a second switching section configured to switch an output destination of a positive-phase voltage and a reversed-phase voltage of the second differential voltage in synchronization with a switching cycle of the first switching section between two output sections of the first transconductance amplifier.

3. The transconductance adjusting circuit according to claim 1, wherein the first resistor section and the second resistor section are each a switched capacitor circuit.

4. The transconductance adjusting circuit according to claim 1, wherein the first transconductance amplifier includes:
a first line that makes a connection between a power supply and a ground;
a second line that makes a connection between the power supply and the ground;
a current pair having a first transistor and a second transistor;
a differential pair having a third transistor and a fourth transistor; and
a fifth transistor that makes a connection between the first line and the second line at downstream of the differential pair, and
wherein the first transistor is provided on the first line,
the second transistor is provided on the second line,
the third transistor is provided at downstream of the first transistor on the first line,
the fourth transistor is provided at downstream of the second transistor on the second line,
the second control voltage is supplied to a control terminal of the first transistor and a control terminal of the second transistor,
the first differential voltage is supplied between a control terminal of the third transistor and a control terminal of the fourth transistor,
a voltage difference between a first voltage and a second voltage is output as the second differential voltage, the first voltage being generated at a node between the first transistor and the third transistor on the first line, the second voltage being generated at a node between the second transistor and the fourth transistor on the second line, and
the first control voltage is supplied to a control terminal of the fifth transistor.

5. A filter circuit, comprising:
a transconductance adjusting circuit, the transconductance adjusting circuit including
a voltage generating section configured to generate a first differential voltage,
a first transconductance amplifier configured to receive the first differential voltage through a first positive-phase voltage transmission line and a first reversed-phase voltage transmission line, and output a second differential voltage through a second positive-phase voltage transmission line and a second reversed-phase voltage transmission line,
a first control section configured to receive the second differential voltage and supply a feedback of a first control voltage to the first transconductance amplifier,
a second control section configured to receive the second differential voltage and supply a feedback of a second control voltage to the first transconductance amplifier,
a first resistor section that makes a connection between the first positive-phase voltage transmission line and the second positive-phase voltage transmission line, and
a second resistor section that makes a connection between the first reversed-phase voltage transmission line and the second reversed-phase voltage transmission line; and
a second transconductance amplifier configured to received the first control voltage from the first control section.

6. The filter circuit according to claim 5, wherein the second transconductance amplifier receives a differential signal and outputs a differential signal.

7. The filter circuit according to claim 5, further comprising a third control section configured to receive a differential signal output from the second transconductance amplifier and supply a feedback of a third control voltage to the second transconductance amplifier.

8. An electronic apparatus provided with a filter circuit, the filter circuit comprising:
a transconductance adjusting circuit, the transconductance adjusting circuit including
a voltage generating section configured to generate a first differential voltage,
a first transconductance amplifier configured to receive the first differential voltage through a first positive-phase voltage transmission line and a first reversed-phase voltage transmission line, and output a second differential voltage through a second positive-phase voltage transmission line and a second reversed-phase voltage transmission line,
a first control section configured to receive the second differential voltage and supply a feedback of a first control voltage to the first transconductance amplifier,
a second control section configured to receive the second differential voltage and supply a feedback of a second control voltage to the first transconductance amplifier,
a first resistor section that makes a connection between the first positive-phase voltage transmission line and the second positive-phase voltage transmission line, and
a second resistor section that makes a connection between the first reversed-phase voltage transmission line and the second reversed-phase voltage transmission line; and
a second transconductance amplifier configured to received the first control voltage from the first control section.
